(19) United States
(12) Patent Application Publication
(10) Pub. No.: US 2026/0076074 A1
(43) Pub. Date: Mar. 12, 2026

(54) ELECTRONIC DEVICE AND DISPLAY DEVICE

(71) Applicant: Samsung Display Co., Ltd., Yongin-si (KR)

(72) Inventors: SEUNGHO KIM, Yongin-si (KR); BYUNGHOON KANG, Yongin-si (KR); SANGHOON KIM, Yongin-si (KR); JINGYU SIM, Yongin-si (KR); SEONGJIN HWANG, Yongin-si (KR)

(21) Appl. No.: 19/295,200

(22) Filed: Aug. 8, 2025

(30) Foreign Application Priority Data
Sep. 11, 2024 (KR) 10-2024-0124067

(51) Int. Cl. H10K 59/80; H10K 102/00

(52) U.S. Cl. CPC H10K 59/873; H10K 2102/311

(57) ABSTRACT

An electronic device includes: a display module; and a window on the display module. The window includes: a window base on the display module, and including: a folding portion having one surface of the window base partially engraved by a groove; and a first non-folding portion and a second non-folding portion spaced from each other with the folding portion between the first and second non-folding portions; and a resin layer on the one surface of the window base, and including: a first resin portion on the folding portion to fill the groove; and a second resin portion on the first non-folding portion and the second non-folding portion.

### CROSS-REFERENCE TO RELATED APPLICATION(S)

The present application claims priority to and the benefit of Korean Patent Application No. 10-2024-0124067, filed on Sep. 11, 2024, in the Korean Intellectual Property Office, the entire disclosure of which is incorporated by reference herein.

### BACKGROUND

### 1. Field

Aspects of embodiments of the present disclosure relate to an electronic device and a display device, which may include a window.

### 2. Description of Related Art

An electronic device includes a display device including a display area that is activated in response to electrical signals. The display device senses an input applied thereto from the outside through the display area, and displays images to provide a user with information through the display area. Recently, display devices having a variety of shapes are being developed, and research on foldable display devices are actively being conducted.

The above information disclosed in this Background section is for enhancement of understanding of the background of the present disclosure, and therefore, it may contain information that does not constitute prior art.

### SUMMARY

In order to improve the impact resistance of ultra-thin glass (UTG) having foldable characteristics, while preventing the separation of a display module and the ultra-thin glass from each other during a folding operation, the physical properties of a resin layer placed on one surface of the ultra-thin glass may be adjusted.

Embodiments of the present disclosure may be directed to an electronic device and a display device including a window having a foldable property and improved reliability. For example, in some embodiments, the window may include a foldable window base, and a resin layer disposed on one surface of the foldable window base.

According to one or more embodiments of the present disclosure, an electronic device includes: a display module; and a window on the display module, the window including: a window base on the display module, and including: a folding portion having one surface of the window base partially engraved by a groove; and a first non-folding portion and a second non-folding portion spaced from each other with the folding portion between the first and second non-folding portions; and a resin layer on the one surface of the window base, and including: a first resin portion on the folding portion to fill the groove; and a second resin portion on the first non-folding portion and the second non-folding portion. The resin layer has a Young's modulus equal to or greater than about 60 MPa and equal to or smaller than about 1000 MPa at a temperature of about-20 degrees Celsius, equal to or greater than about 35 MPa equal to or smaller than about 1000 MPa at a temperature of about 25 degrees Celsius, and equal to or greater than about 10 MPa equal to or smaller than about 1000 MPa at a temperature of about 60 degrees Celsius.

In an embodiment, the folding portion may include a first surface adjacent to the display module, and a second surface opposite to the first surface. The groove may be engraved in the first surface.

In an embodiment, the Young's modulus of the resin layer may be equal to or greater than about 70 MPa and equal to or smaller than about 1000 MPa at a temperature of about-20 degrees Celsius, equal to or greater than about 40 MPa equal to or smaller than about 1000 MPa at a temperature of about 25 degrees Celsius, and equal to or greater than about 20 MPa equal to or smaller than about 1000 MPa at a temperature of about 60 degrees Celsius.

In an embodiment, the folding portion may include a first surface adjacent to the display module, and a second surface opposite to the first surface. The groove may be engraved in the second surface.

In an embodiment, the first non-folding portion may include a first non-folding surface; the second non-folding portion may include a second non-folding surface; and the folding portion may include a flat surface, a first slant surface connecting the flat surface and the first non-folding surface to each other, and a second slant surface connecting the flat surface and the second non-folding surface to each other.

In an embodiment, the first resin portion may be in contact with each of the flat surface, the first slant surface, and the second slant surface.

In an embodiment, the groove may include the flat surface, the first slant surface, and the second slant surface.

In an embodiment, the resin layer may have a refractive index equal to or greater than about 1.45 and equal to or smaller than about 1.54 with respect to visible light.

In an embodiment, an absolute value of a crack strain of the resin layer may be equal to or smaller than about 10%.

In an embodiment, the folding portion may have a thickness equal to or

greater than about 30 micrometers and equal to or smaller than about 70 micrometers; the first non-folding portion may have a thickness equal to or greater than about 120 micrometers and equal to or smaller than about 180 micrometers; and the second non-folding portion may have a thickness equal to or greater than about 120 micrometers and equal to or smaller than about 180 micrometers.

In an embodiment, the resin layer may further include a third resin portion in contact with a side surface of the window base.

In an embodiment, the first resin portion, the second resin portion, and the third resin portion may be integral with each other.

In an embodiment, the first resin portion may have a thickness equal to or greater than about 50 micrometers and equal to or smaller than about 150 micrometers, and the second resin portion may have a thickness equal to or greater than about 5 micrometers and equal to or smaller than about 30 micrometers.

According to one or more embodiments of the present disclosure, a display device includes: a lower protective film; a base layer on the lower protective film; a display element layer on the base layer; and a window including: a window base on the display element layer, and including: a folding portion having one surface of the window base engraved by a groove; and a first non-folding portion and a second non-folding portion spaced from each other with the folding portion between the first and second non-folding portions; and a resin layer on the one surface of the window base. The resin layer has a Young's modulus equal to or greater than about 60 MPa and equal to or smaller than about 1000 MPa at a temperature of about-20 degrees Celsius, equal to or greater than about 35 MPa equal to or smaller than about 1000 MPa at a temperature of about 25 degrees Celsius, and equal to or greater than about 10 MPa and equal to or smaller than about 1000 MPa at a temperature of about 60 degrees Celsius.

In an embodiment, the resin layer may include: a first resin portion directly in the groove; and a second resin portion directly on the first non-folding portion and the second non-folding portion.

In an embodiment, the display device may further include a barrier layer on a lower surface of the lower protective film.

In an embodiment, the barrier layer may have a thickness equal to or greater than about 20 micrometers and equal to or smaller than about 40 micrometers.

In an embodiment, the display device may further include a protective layer on the resin layer.

In an embodiment, the protective layer may have a thickness equal to or greater than about 30 micrometers and equal to or smaller than about 60 micrometers.

In an embodiment, the folding portion may include a first surface adjacent to the display element layer, and a second surface opposite to the first surface; the groove may be engraved in the first surface; and the Young's modulus of the resin layer may be equal to or greater than about 70 MPa and equal to or smaller than about 1000 MPa at a temperature of about-20 degrees Celsius, equal to or greater than about 40 MPa equal to or smaller than about 1000 MPa at a temperature of about 25 degrees Celsius, and equal to or greater than about 20 MPa equal to or smaller than about 1000 MPa at a temperature of about 60 degrees Celsius.

According to some embodiments of the present disclosure, an electronic device and a display device may include a window including a window base provided with a groove engraved in one surface thereof, and a resin layer disposed on the one surface of the window base. Accordingly, the impact resistance characteristics and a buckling phenomenon during folding may be improved.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIGS. 1A-1C are perspective views of a display device according to an embodiment of the present disclosure;

FIG. 2 is an exploded perspective view of a display device according to an embodiment of the present disclosure;

FIG. 3 is an exploded perspective view of a display device according to an embodiment of the present disclosure;

FIG. 4 is a cross-sectional view of a display module taken along the line I-I′ of FIG. 2;

FIG. 5 is a cross-sectional view of a display device taken along the line II-II′ of FIG. 2;

FIG. 6 is an enlarged cross-sectional view of the area AA′ of FIG. 5;

FIG. 7 is a cross-sectional view of a display device taken along the line II-II′ of FIG. 2 according to an embodiment of the present disclosure;

FIG. 8 is a cross-sectional view of a display device taken along the line II-II′ of FIG. 2 according to an embodiment of the present disclosure; and

FIG. 9 is a cross-sectional view of a display device taken along the line III-III′ of FIG. 3 according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

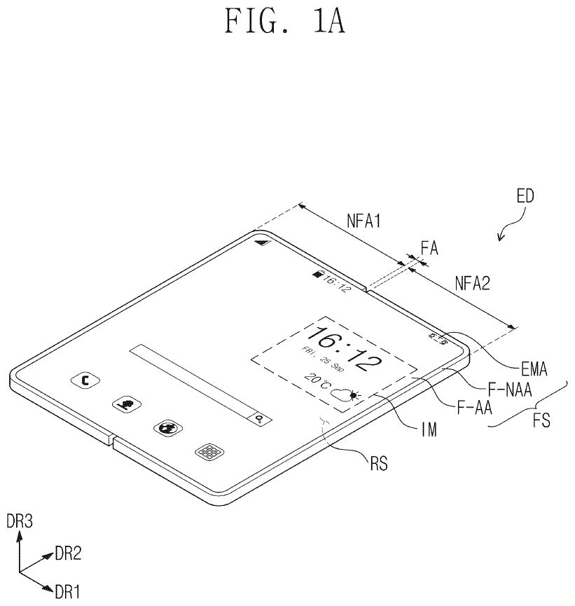

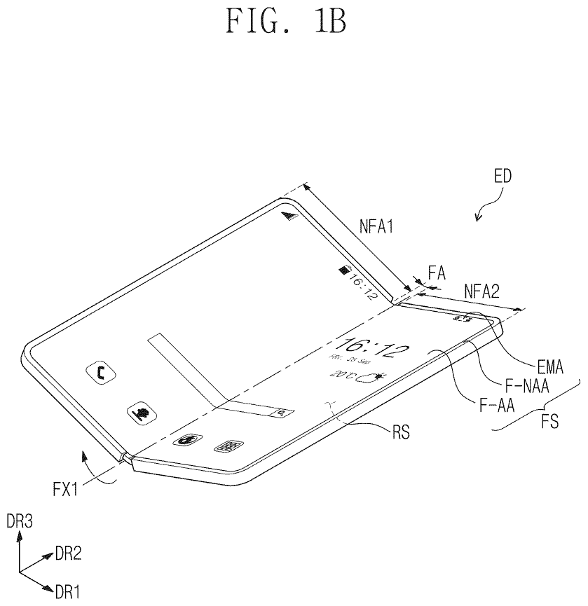

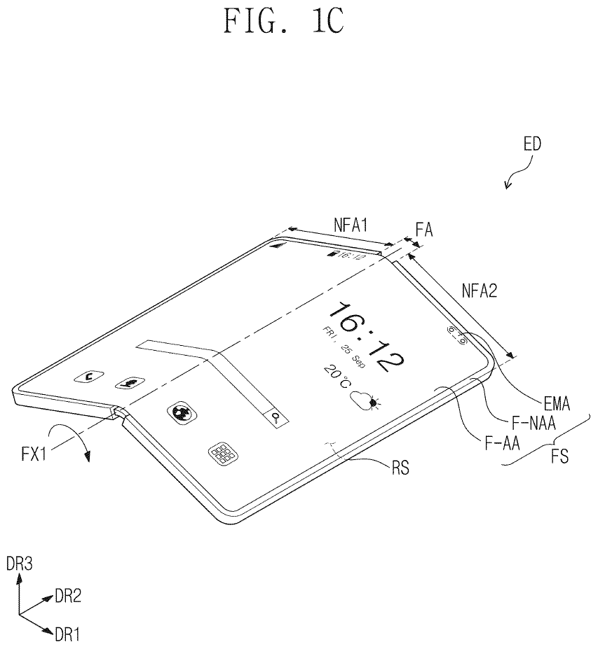

FIGS. 1A through 1C are perspective views of a display device ED according to an embodiment of the present disclosure. FIG. 1A shows an unfolded state of the display device ED, and FIGS. 1B and 1C each show a folded state of the display device ED.

FIGS. 1A to 1C show a foldable display device as the display device ED, however, the present disclosure is not limited thereto or thereby. The display device ED may be a flexible display device that is bendable or rollable.

The display device ED may include a display surface FS defined by a first direction DR1, and a second direction DR2 intersecting or crossing the first direction DR1. The display device ED may provide an image IM to a user through the display surface FS. The display device ED may display the image IM through the display surface FS, which is parallel to or substantially parallel to each of the first direction DR1 and the second direction DR2, toward a third direction DR3.

The display surface FS of the display device ED may include an active area F-AA and a peripheral area F-NAA. The active area F-AA of the display device ED may be activated in response to electrical signals. The display device ED may display the image IM through the active area F-AA. In addition, various suitable external inputs may be sensed through the active area F-AA. The peripheral area F-NAA may be defined adjacent to the active area F-AA. The peripheral area F-NAA may have a suitable color (e.g., a predetermined color). The peripheral area F-NAA may surround (e.g., around a periphery of) the active area F-AA. Accordingly, the active area F-AA may have a shape that is defined or substantially defined by the peripheral area F-NAA, however, the present disclosure is not limited thereto. The peripheral area F-NAA may be defined adjacent to one side (e.g., only one side) of the active area F-AA, or may be omitted as needed or desired. According to an embodiment, the display device ED may include the active area having various suitable shapes, and is not particularly limited.

The active area F-AA may include a sensing area EMA. Various suitable electronic modules (e.g., electronic devices or sensors) may be disposed in the sensing area EMA. As an example, the electronic module may include at least one of a camera module (e.g. a camera), a speaker, an optical sensor, or a thermal sensor. An external object may be sensed through the sensing area EMA of the display surface FS, and/or a sound signal, such as a voice, may be provided to the outside through the sensing area EMA of the display surface FS. The electronic module may include a plurality of suitable components, and is not particularly limited.

The sensing area EMA may be surrounded (e.g., around a periphery thereof) by the active area F-AA and the peripheral area F-NAA, however, it is not limited thereto or thereby. The sensing area EMA may be defined in the active area F-AA, but is not particularly limited thereto. FIG. 1A shows one sensing area EMA as a representative example, however, the number of sensing areas EMA is not limited thereto or thereby.

The sensing area EMA may be a portion of the active area F-AA. Accordingly, the display device ED may also display an image through the sensing area EMA. When the electronic modules disposed in the sensing area EMA are deactivated, the sensing area EMA may serve as part of the display surface to display the image IM.

The display device ED may include a rear surface RS opposite to the display surface FS. The rear surface RS may be an external surface of the display device ED, and the image IM may not be displayed through the rear surface RS, however, it is not limited thereto or thereby. According to an embodiment, the rear surface RS may serve as a second display surface through which an image is displayed. In addition, in some embodiments, the display device ED may further include a sensing area defined in the rear surface RS. A camera, a speaker, and/or an optical sensor may be disposed in the sensing area defined in the rear surface RS.

The display device ED may include a folding area FA and non-folding areas NFA1 and NFA2. The display device ED may include a plurality of non-folding areas NFA1 and NFA2. According to the present embodiment, the display device ED may include first and second non-folding areas NFA1 and NFA2 disposed adjacent to each other with the folding area FA interposed therebetween. While FIGS. 1A to 1C show the display device ED including one folding area FA, the present disclosure is not limited thereto or thereby. According to an embodiment, the display device ED may include a plurality of folding areas defined therein. According to an embodiment, the display device ED may be folded with respect to a plurality of folding axes to allow portions of the display surface FS to face each other, and the number of the folding axes and the number of the non-folding areas are not particularly limited.

Referring to FIGS. 1B and 1C, the display device ED may be folded with respect to a folding axis FX1 extending in one direction. The folding axis FX1 shown in FIGS. 1B and 1C may be an imaginary axis extending in the second direction DR2 to be parallel to or substantially parallel to a direction in which a long side of the display device ED extends. However, the direction in which the folding axis FX1 extends is not limited to the second direction DR2.

The folding axis FX1 may extend in the second direction DR2 on the display surface FS, or may extend in the second direction DR2 under the rear surface RS. Referring to FIG. 1B, the display device ED may be inwardly folded (e.g., in-folding) to allow the first non-folding area NFA1 and the second non-folding area NFA2 to face each other, and thus, the display surface FS may not be exposed to the outside. In addition, referring to FIG. 1C, the display device ED may be outwardly folded (e.g., out-folding) with respect to the folding axis FX1 to allow a portion of the rear surface RS, which overlaps with the first non-folding area NFA1, to face another portion of the rear surface RS, which overlaps with the second non-folding area NFA2.

The display device ED may repeat the unfolding operation and the in-folding operation, or may repeat the unfolding operation and the out-folding operation, however, the present disclosure is not limited thereto or thereby. According to an embodiment, the display device ED may be selectively operated in any one of the unfolding operation, the in-folding operation, and the out-folding operation.

FIGS. 1A to 1C show the display device ED folded with respect to the folding axis FX1 that is parallel to or substantially parallel to the long side of the display device ED, however, the present disclosure is not limited thereto or thereby. According to an embodiment, the display device ED may be folded with respect to a folding axis that is parallel to or substantially parallel to a short side of the display device ED.

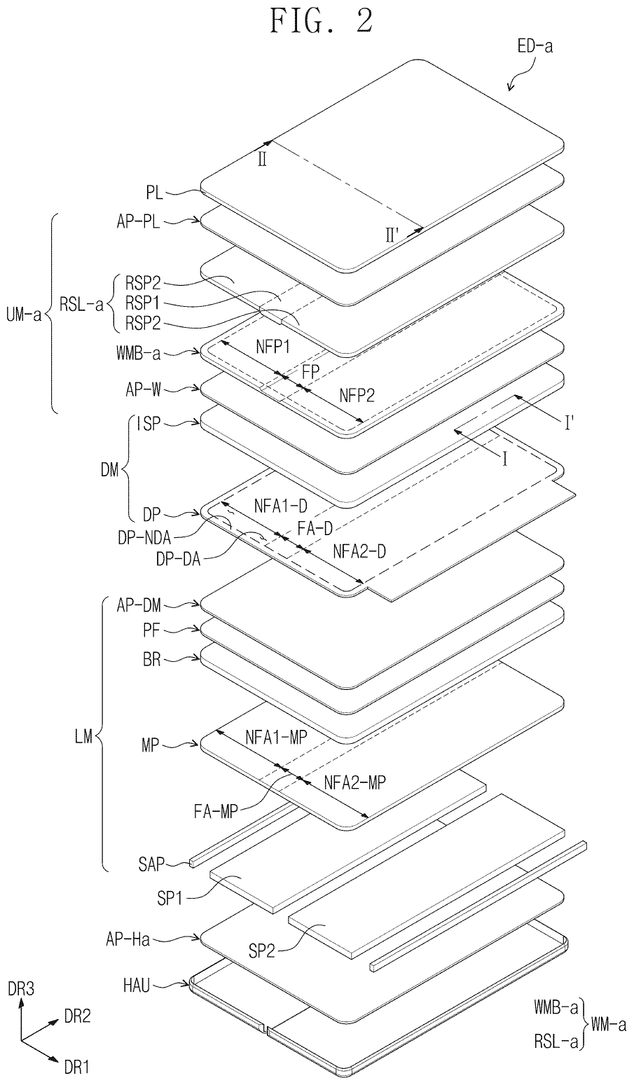

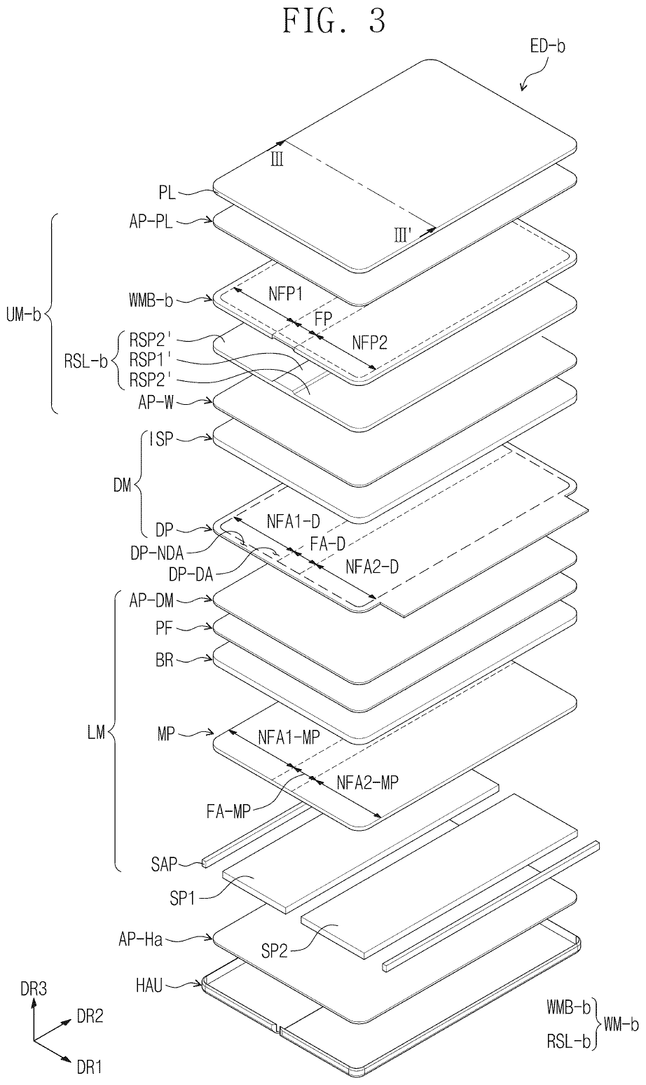

FIG. 2 is an exploded perspective view of a display device ED-a according to an embodiment of the present disclosure. FIG. 3 is an exploded perspective view of a display device ED-b according to an embodiment of the present disclosure. FIGS. 2 and 3 may be exploded perspective views of the display device ED shown in FIG. 1A.

Referring to FIG. 2, the display device ED-a may include a display module (e.g., a display or a touch-display) DM and a window WM-a. The display device ED-a may include the display module DM, an upper module (e.g., an upper layer or stack) UM-a disposed on the display module DM, and a lower module (e.g., a lower layer or stack) LM disposed under the display module DM. Hereinafter, the upper module UM-a may be referred to as a protective member, and the lower module LM may be referred to as a support member.

The upper module UM-a disposed on the display module DM may function as a protective part to protect the display module DM from external impacts, or may function as an optical part to prevent or substantially prevent a reflection of external light and/or to increase a light extraction efficiency.

The upper module UM-a may include the window WM-a disposed above the display module DM, a protective layer PL disposed above the window WM-a, and a protective layer adhesive layer AP-PL disposed between the window WM-a and the protective layer PL.

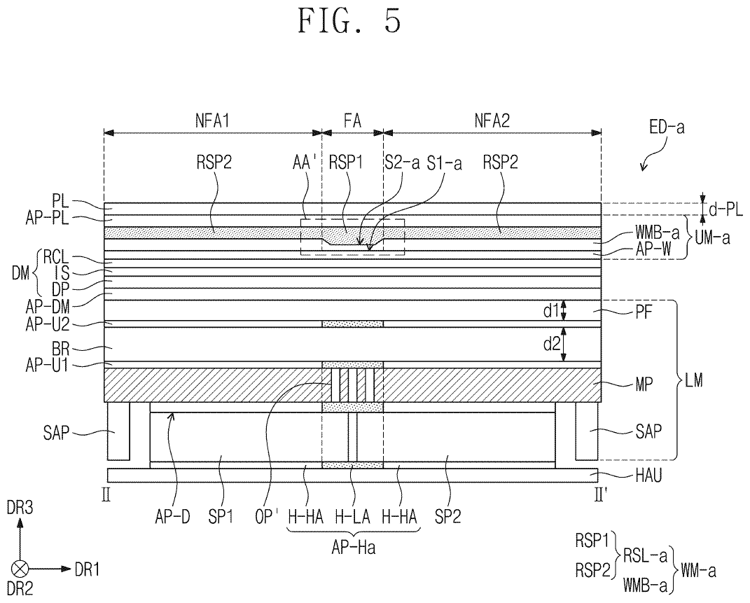

The window WM-a may cover an entire upper surface of the display module DM. The window WM-a may have a suitable shape corresponding to a shape of the display module DM. The window WM-a may include a window base WMB-a and a resin layer RSL-a. In the display device ED-a, the window base WMB-a may be disposed above the display module DM. The window base WMB-a may include an optically transparent insulating material. The window base WMB-a may include a glass substrate or a polymer substrate. As an example, the window base WMB-a may be a tempered glass substrate. The window base WMB-a according to some embodiments of the present disclosure may have a step difference formed between a folding portion FP, which corresponds to the folding area FA (e.g., refer to FIG. 1A), and non-folding portions NFP1 and NFP2, which correspond to the non-folding areas NFA1 and NFA2, and thus, may enhance the folding characteristics of the display device ED-a. The shape of the window base WMB-a will be described in more detail below with reference to FIG. 5.

The resin layer RSL-a may be disposed on one surface of the window base WMB-a. The resin layer RSL-a may be disposed on an upper surface of the window base WMB-a as shown in FIG. 2. The resin layer RSL-a may be disposed directly on the upper surface of the window base WMB-a. However, the present disclosure is not limited thereto, and as shown in FIG. 3, the resin layer RSL-b may be disposed under the window base WMB-b. The resin layer RSL-a may include a first resin portion RSP1 corresponding to the folding portion FP, and a second resin portion RSP2 corresponding to the non-folding portions NFP1 and NFP2. The resin layer RSL-a may include an acrylic resin, an epoxy resin, a silicone resin, a urethane resin, a urethane acrylic resin, a hybrid sol-gel, and/or a siloxane resin. As an example, the resin layer RSL-a may include the acrylic resin. The resin layer RSL-a may include a portion that is embossed to correspond to a groove engraved in one surface of the window base WMB-a. Because the resin layer RSL-a according to some embodiments of the present disclosure may have a Young's modulus within a suitable range as described in more detail below, the resin layer RSL-a disposed on the one surface of the window base WMB-a may prevent or substantially prevent a buckling phenomenon from occurring when the display device ED-a is folded, and thus, a durability of the display device ED-a may be increased. The shape of the resin layer RSL-a will be described in more detail below with reference to FIG. 5

The upper module UM-a may further include a window adhesive layer AP-W disposed under the window WM-a. The window adhesive layer AP-W may be disposed between the display module DM and the window WM-a. The window adhesive layer AP-W may be an optically clear adhesive (OCA) film or an optically clear adhesive resin (OCR) layer. According to an embodiment, the window adhesive layer AP-W may be omitted as needed or desired.

The protective layer PL may be disposed above the window WM-a, and may protect the window WM-a from external environments. The protective layer PL may be transparent, and thus, image information (e.g., refer to the image IM of FIG. 1A) provided from the display module DM may be viewed even though the protective layer PL is disposed. The protective layer PL may be the uppermost surface of the display device ED-a that is exposed, and the protective layer PL may be damaged depending on the use of the display device ED-a. The protective layer PL may have a thickness d-PL (e.g., refer to FIG. 5) equal to or greater than about 30 micrometers, and equal to or smaller than about 60 micrometers. As an example, the protective layer PL may have the thickness d-PL of about 35 micrometers.

The protective layer PL may have optical characteristics including a transmittance of about 90% or more in a visible light region, and a haze value of less than about 1%. The protective layer PL may include a polymer film. In addition, the protective layer PL may have the polymer film as its base layer, and may further include a functional layer, such as a hard coating layer, an anti-fingerprint coating layer, an antistatic coating layer, or the like, on the base layer. The protective layer PL used in the display device ED-a may have a suitable flexibility.

The protective layer PL may be a polymer film including at least one polymer resin among polyethylene terephthalate (PET), polybutylene terephthalate (PBT), polyethylene naphthalene (PEN), polycarbonate (PC), polymethylmethacrylate (PMMA), polystyrene (PS), polyvinylchloride (PVC), polyethersulfone (PES), polypropylene (PP), polyamide (PA), a modified polyphenylene ether (m-PPO), polyoxymethylene (POM), polysulfone (PSU), polyphenylene sulfide (PPS), polyimide (PI), polyethyleneimine (PEI), polyether ether ketone (PEEK), polyamide imide (PAI), polyarylate (PAR), or a thermoplastic polyurethane (TPU).

As an example, the protective layer PL may be a polyethylene terephthalate (PET) film or a thermoplastic polyurethane (TPU) film. In addition, the protective layer PL may be a PET film without a phase delay.

According to some embodiments of the display device ED-a, the protective layer adhesive layer AP-PL may be disposed between the window WM-a and the protective layer PL. The protective layer adhesive layer AP-PL may be an optically clear adhesive layer. The protective layer adhesive layer AP-PL may be attached to the window WM-a to fix the protective layer PL to the window WM-a.

The display device ED-a according to an embodiment may include a housing HAU that accommodates the display module DM and the lower module LM. The housing HAU may be coupled to the window WM-a. The housing HAU may further include a hinge structure for more easy folding or bending. The hinge structure may be disposed to correspond to the folding area FA.

The display device ED-a according to an embodiment may include a housing adhesive layer AP-Ha. The housing adhesive layer AP-Ha may function to fix the lower module LM to the housing HAU. The housing adhesive layer AP-Ha may include a folding adhesive portion H-LA (e.g., refer to FIG. 5) corresponding to the folding area FA, and non-folding adhesive portions H-HA corresponding to the non-folding areas NFA1 and NFA2. The housing adhesive layer AP-Ha may be an adhesive member to allow the lower module LM to be coupled to the housing HAU, and may also function as an electromagnetic shielding layer or a heat dissipation layer.

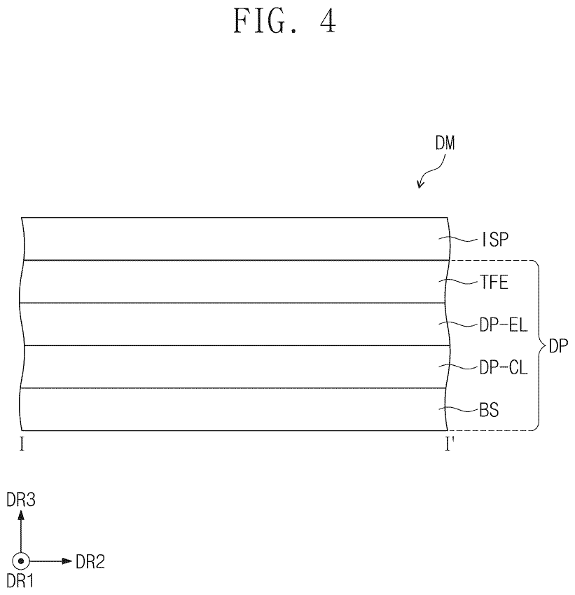

The display module DM may include a display panel DP, and an input sensing layer ISP disposed on the display panel DP. The display panel DP and the input sensing layer ISP will be described in more detail below with reference to FIG. 4.

According to some embodiments of the display device ED-a, the display module DM may include a folding display portion FA-D and non-folding display portions NFA1-D and NFA2-D. The folding display portion FA-D may correspond to the folding area FA (e.g., refer to FIG. 1A), and the non-folding display portions NFA1-D and NFA2-D may correspond to the non-folding areas NFA1 and NFA2.

The folding display portion FA-D may be folded or bent with respect to the folding axis FX1 (e.g., refer to FIG. 1B or 1C). The display module DM may include a first non-folding display portion NFA1-D and a second non-folding display portion NFA2-D, and the first non-folding display portion NFA1-D and the second non-folding display portion NFA2-D may be spaced apart from each other with the folding display portion FA-D interposed therebetween.

The display device ED-a may further include a module adhesive layer AP-DM disposed between the display module DM and the lower module LM. The module adhesive layer AP-DM may be an optically clear adhesive (OCA) film or an optically clear adhesive resin (OCR) layer.

According to some embodiments of the display device ED-a, the lower module LM may include a support plate MP, and adhesive layers AP-U1, AP-U2, and AP-D (e.g., refer to FIG. 5) disposed above and under the support plate MP. In addition, the lower module LM may further include at least one of support portions SP1 and SP2, a filling portion SAP, a lower protective film PF, or a barrier layer BR. As an example, the display device ED-a may include the support plate MP disposed under the display module DM, the lower protective film PF and the barrier layer BR disposed between the support plate MP and the display module DM, and the support portions SP1 and SP2 and the filling portion SAP disposed under the support plate MP.

The support plate MP may be disposed under the display module DM. The support plate MP may include a folding support portion FA-MP and non-folding support portions NFA1-MP and NFA2-MP. Hereinafter, the folding support portion FA-MP may be referred to as a folding portion, and the non-folding support portions NFA1-MP and NFA2-MP may be referred to as non-folding portions. A first non-folding portion NFA1-MP and a second non-folding portion NFA2-MP of the support plate MP may be spaced apart from each other with the folding portion FA-MP interposed therebetween. The folding portion FA-MP may correspond to the folding area FA, and the non-folding portions NFA1-MP and NFA2-MP may correspond to the non-folding areas NFA1 and NFA2.

The support plate MP may include a metal material or a polymer material. As an example, the support plate MP may include stainless steel, aluminum, or a suitable alloy thereof. In addition, according to an embodiment, the support plate MP may include a carbon fiber reinforced plastic (CFRP), however, the present disclosure is not limited thereto or thereby. According to an embodiment, the support plate MP may include at least one of a non-metallic material, a plastic material, a glass fiber reinforced plastic, or a glass material.

The support plate MP may be provided with a plurality of openings OP′ (e.g., refer to FIG. 5) defined therethrough. The openings OP′ may be defined to correspond to the folding area FA.

The lower protective film PF may be disposed between the display module DM and the support plate MP. The lower protective film PF may be disposed under the display module DM, and may protect a rear surface of the display module DM. The lower protective film PF may entirely overlap with the display module DM. The lower protective film PF may include a polymer material. As an example, the lower protective layer PF may be a polyimide film or a polyethylene terephthalate film, however, the materials for the lower protective film PF are not limited thereto or thereby. The lower protective film PF may have a thickness d1 (e.g., refer to FIG. 5) equal to or greater than about 30 micrometers, and equal to or smaller than about 70 micrometers. As an example, the thickness d1 of the lower protective film PF may be about 50 micrometers.

The display device ED-a may include the support portions SP1 and SP2 and the filling portion SAP. The support portions SP1 and SP2 may overlap with most of the display module DM. The filling portion SAP may be disposed outside the support portions SP1 and SP2, and may overlap with an outer portion of the display module DM.

The support portions SP1 and SP2 may include a first sub-support portion SP1, and a second sub-support portion SP2 spaced apart from the first sub-support portion SP1 in the first direction DR1. The first sub-support portion SP1 and the second sub-support portion SP2 may be spaced apart from each other in an area corresponding to the folding axis FX1 (e.g., refer to FIG. 1B). As the support portions SP1 and SP2 are provided as the first sub-support portion SP1 and the second sub-support portion SP2 that are spaced apart from each other in the folding area FA, the folding or bending characteristics of the display device ED-a may be improved. In some embodiments, the lower module LM may further include a cushion layer disposed above or under the support portions SP1 and SP2. The cushion layer may include sub-cushion layers spaced apart (e.g., separated) from each other in an area corresponding to the folding axis FX1 (e.g., refer to FIG. 1B or FIG. 1C). A lower adhesive layer, which has a lower adhesive force in an area corresponding to the folding area FA than that in an area corresponding to the non-folding areas NFA1 and NFA2, may be further disposed between the support portions SP1 and SP2 and the cushion layer.

The cushion layer may prevent or substantially prevent the support plate MP from being pressed and deformed due to an external impact and force. The cushion layer may include a sponge, a foam, or an elastomer, such as a urethane resin. In addition, the cushion layer may include at least one of an acrylic-based polymer, a urethane-based polymer, a silicon-based polymer, or an imide-based polymer, however, it is not limited thereto or thereby. According to an embodiment, the cushion layer may be disposed under the support plate MP, or under a lower support plate.

The filling portion SAP may be disposed outside the support portions SP1 and SP2. The filling portion SAP may be disposed between the support plate MP and the housing HAU. The filling portion SAP may be filled in a space between the support plate MP and the housing HAU, and may fix the support plate MP.

The display device ED-a may include the barrier layer BR included in the lower module LM. The barrier layer BR may serve as a thickness compensation layer to compensate for a difference in a thickness of the components disposed under the display module DM, or may serve as a support layer to support the display module DM. The barrier layer BR may have a thickness d2 (e.g., refer to FIG. 5) equal to or greater than about 20 micrometers, and equal to or smaller than about 40 micrometers. As an example, the thickness d2 of the barrier layer BR may be about 25 micrometers. However, the present disclosure is not limited thereto, and in an embodiment, the barrier layer BR may be omitted as needed or desired.

A combination of the components included in the lower module LM in the display device ED-a is not limited thereto or thereby, and may be variously modified depending on the size, the shape, or the operating characteristics of the display device ED-a. As an example, the lower module LM may further include other components, such as an additional support plate, a cushion member, an adhesive layer, and/or the like.

The lower module LM of the display device ED-a may include one or more upper adhesive layers AP-U1 and AP-U2 (e.g., refer to FIG. 5) disposed above the support plate MP, and at least one lower adhesive layer AP-D disposed under the support plate MP.

FIG. 4 is a cross-sectional view of the display module taken along the line I-I′ of FIG. 2.

Referring to FIG. 4, the display panel DP may have a suitable configuration that substantially generates an image. The display panel DP may be a light-emitting kind of display panel. For example, the display panel DP may be an organic light emitting display panel, an inorganic light emitting display panel, a micro-LED display panel, a micro-OLED display panel, or a nano-LED display panel or layer.

The display panel DP may include a display area DP-DA (e.g., see FIG. 2) and a non-display area DP-NDA. The display area DP-DA may be defined as an area in which the image provided from the display panel DP is displayed.

The non-display area DP-NDA may be defined adjacent to the display area DP-DA. As an example, the non-display area DP-NDA may surround (e.g., around a periphery of) the display area DP-DA, however, the present disclosure is not limited thereto. According to an embodiment, the non-display area DP-NDA may have various suitable shapes, and is not particularly limited. The display area DP-DA of the display panel DP may correspond to at least a portion of the active area F-AA (e.g., refer to FIG. 1A).

The display panel DP may include a base layer BS, a circuit layer DP-CL, a display element layer DP-EL, and an encapsulation layer TFE, which are sequentially stacked. In some embodiments different from the structure shown in FIG. 4, a functional layer may be further disposed between two layers that are adjacent to each other among the base layer BS, the circuit layer DP-CL, the display element layer DP-EL, and the encapsulation layer TFE.

The base layer BS may provide a base surface on which the circuit layer DP-CL is disposed. The base layer BS may be a flexible substrate that is bendable, foldable, or rollable. The base layer BS may be a glass substrate, a metal substrate, or a polymer substrate, however, it is not limited thereto or thereby. According to an embodiment, the base layer BS may be an inorganic layer, an organic layer, or a composite material layer.

The base layer BS may have a single-layer or multi-layered structure. For example, the base layer BS may include a first synthetic resin layer, an inorganic layer having a single-layer or multi-layered structure, and a second synthetic resin layer disposed on the inorganic layer having the single-layer or multi-layered structure. Each of the first and second synthetic resin layers may include a polyimide-based resin. In addition, each of the first and second synthetic resin layers may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. As used herein, the term “X-based resin” refers to a resin that includes a functional group of X.

The circuit layer DP-CL may be disposed on the base layer BS. The circuit layer DP-CL may include an insulating layer, a semiconductor pattern, a conductive pattern, and a signal line. The display element layer DP-EL may be disposed on the circuit layer DP-CL. The display element layer DP-EL may include a light emitting element. As an example, the light emitting element may include an organic light emitting material, an inorganic light emitting material, an organic-inorganic light emitting material, a quantum dot, a quantum rod, a micro-LED, or a nano-LED.

The encapsulation layer TFE may be disposed on the display element layer DP-EL. The encapsulation layer TFE may protect the display element layer DP-EL from moisture, oxygen, and foreign substances, such as dust particles. The encapsulation layer TFE may include at least one inorganic layer. As an example, the encapsulation layer TFE may include an inorganic layer, an organic layer, and an inorganic layer, which are sequentially stacked.

The input sensing layer ISP may be disposed on the display panel DP. The input sensing layer ISP may be disposed directly on the encapsulation layer TFE, however, the present disclosure is not limited thereto or thereby. According to an embodiment, an adhesive member may be disposed between the input sensing layer ISP and the display panel DP.

The input sensing layer ISP may sense an external input, may convert the sensed input to an input signal (e.g., a predetermined input signal), and may provide the input signal to the display panel DP. As an example, the input sensing layer ISP may be a touch sensing layer that senses a touch event. The input sensing layer ISP may sense a direct touch of the user, an indirect touch of the user, a direct touch of an object, or an indirect touch of an object.

The input sensing layer ISP may sense at least one of a position of a touch event applied from the outside or an intensity (e.g., a pressure) of the touch event applied from the outside. The input sensing layer ISP may have various suitable structures or may include various suitable materials, but it is not particularly limited. As an example, the input sensing layer ISP may sense the external input in a capacitive manner. The display panel DP may receive the input signal from the input sensing layer ISP, and may generate an image corresponding to the input signal.

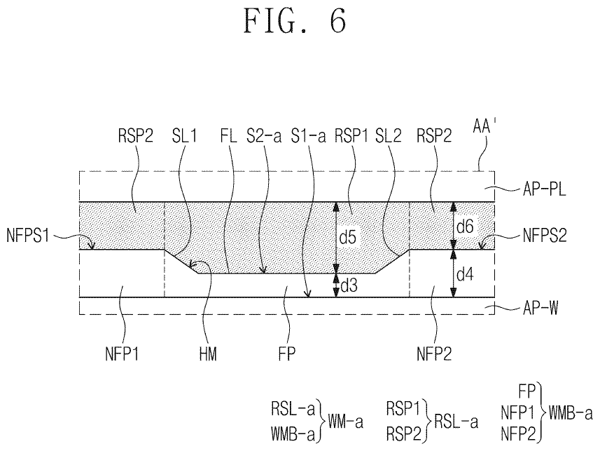

FIG. 5 is a cross-sectional view of the display device ED-a taken along the line II-II′ of FIG. 2. FIG. 6 is an enlarged cross-sectional view of the area AA′ of FIG. 5. In FIGS. 5 and 6, the same reference numerals denote the same or substantially the same elements as those described above with reference to FIGS. 1A to 4, and thus, redundant description thereof may not be repeated.

Referring to FIGS. 5 and 6, the window base WMB-a may include a first surface S1-a adjacent to the display module DM, and a second surface S2-a opposite to the first surface S1-a. The groove HM may be engraved in the one surface of the window base WMB-a. For example, in some embodiments, the groove HM may be engraved in the second surface S2-a of the window base WMB-a.

The window base WMB-a may include the first non-folding portion NFP1, the folding portion FP, and the second non-folding portion NFP2. The folding portion FP may have a thickness d3 equal to or greater than about 30 micrometers, and equal to or smaller than about 70 micrometers. As an example, the thickness d3 of the folding portion FP may be about 50 micrometers. The first non-folding portion NFP1 may have a thickness d4 equal to or greater than about 120 micrometers, and equal to or smaller than about 180 micrometers. The second non-folding portion NFP2 may have the thickness d4 equal to or greater than about 120 micrometers, and equal to or smaller than about 180 micrometers. The thickness d4 of the first non-folding portion NFP1 and the thickness d4 of the second non-folding portion NFP2 may be the same or substantially the same as each other. As an example, the thickness d4 of each of the first non-folding portion NFP1 and the second non-folding portion NFP2 may be about 150 micrometers. The thickness of each of the folding portion FP and the non-folding portions NFP1 and NFP2 of the window base WMB-a according to some embodiments of the present disclosure may be greater than a thickness of each of a folding portion and a non-folding portion of a comparative window base, and thus, impact resistance properties may be improved.

The first non-folding portion NFP1 may include a first non-folding surface NFPS1, and the second non-folding portion NFP2 may include a second non-folding surface NFPS2. The folding portion FP may include a flat surface FL, a first slant surface SL1, and a second slant surface SL2. The first slant surface SL1 may connect the first non-folding surface NFPS1 and the flat surface FL to each other. The second slant surface SL2 may connect the second non-folding surface NFPS2 and the flat surface FL to each other. The groove HM may be defined by the flat surface FL, the first slant surface SL1, and the second slant surface SL2. The first resin portion RSP1 disposed in the groove HM may be in contact with each of the flat surface FL, the first slant surface SL1, and the second slant surface SL2.

The resin layer RSL-a may include the first resin portion RSP1 and the second resin portion RSP2. The first resin portion RSP1 may be disposed in the groove HM. The first resin portion RSP1 may be disposed directly on the folding portion FP. The first resin portion RSP1 may protrude in a direction opposite to the third direction DR3.

The first resin portion RSP1 may have a thickness d5 that is defined by a distance from the flat surface FL to an upper surface of the resin layer RSL-a. The thickness d5 of the first resin portion RSP1 may be equal to or greater than about 50 micrometers, and equal to or smaller than about 150 micrometers. As an example, the thickness d5 of the first resin portion RSP1 may be about 120 micrometers. The second resin portion RSP2 may have a thickness d6 equal to or greater than about 5 micrometers, and equal to or smaller than about 30 micrometers. As an example, the thickness d6 of the second resin portion RSP2 may be about 20 micrometers. A sum of the thickness d3 of the folding portion FP and the thickness d5 of the first resin portion RSP1 may be the same or substantially the same as a sum of the thickness d4 of the non-folding portions NFP1 and NFP2 and the thickness d6 of the second resin portion RSP2.

The Young's modulus of the resin layer RSL-a may be equal to or greater than about 60 MPa and equal to or smaller than about 1000 MPa at a temperature of about-20 degrees Celsius, equal to or greater than about 35 MPa and equal to or smaller than about 1000 MPa at a temperature of about 25 degrees Celsius, and equal to or greater than about 10 MPa and equal to or smaller than about 1000 MPa at a temperature of about 60 degrees Celsius. As an example, in a case where the Young's modulus of the resin layer RSL-a is smaller than about 60 MPa at the temperature of about-20 degrees Celsius, a degree to which the resin layer RSL-a is folded may be greater than a degree to which the display module DM is folded when the display device ED-a is folded, and thus, the buckling phenomenon may occur. In a case where the Young's modulus of the resin layer RSL-a is greater than about 1000 MPa at the temperature of about-20 degrees Celsius, a crack may occur in the protective layer PL disposed on the resin layer RSL-a.

An absolute value of a crack strain of the resin layer RSL-a may be about 10% or less. The crack strain of the resin layer RSL-a may be defined as a value obtained by subtracting the original length of the resin layer RSL-a before a deformation from a length of the resin layer RSL-a when a cracking occurs due to a force applied thereto, and dividing the subtracted value by the original length of the resin layer RSL-a before the deformation. Because a compressive crack strain may be the crack strain when a compressive force is applied to the resin layer RSL-a, the compressive crack strain may be zero (0) or negative, and because a tensile crack strain may be the crack strain when a tensile force is applied to the resin layer RSL-a, the tensile crack strain may be zero (0) or positive. The compressive crack strain of the resin layer RSL-a may be equal to or greater than about-10%. The tensile crack strain of the resin layer RSL-a may be equal to or smaller than about 10%.

The resin layer RSL-a may have a refractive index equal to or greater than about 1.45 and equal to or smaller than about 1.54 with respect to a visible light. As an example, the refractive index of the resin layer RSL-a may be about 1.50 with respect to the visible light. The refractive index of the window base WMB-a with respect to the visible light may be equal to or greater than about 0.9 times and equal to or smaller than about 1.1 times the refractive index of the resin layer RSL-a with respect to the visible light. The refractive index of the window base WMB-a with respect to the visible light may be the same or substantially the same as the refractive index of the resin layer RSL-a with respect to the visible light. In the present disclosure, when two components are described as being “the same or substantially the same”, it means both cases where the two components are physically identical and where the two components are identical in design but have minor differences after processing.

According to some embodiments of the present disclosure, the display device ED-a may include the window WM-a including the window base WMB-a provided with the groove engraved in the one surface thereof, and the resin layer RSL-a disposed on the one surface of the window base WMB-a. Therefore, the folding characteristics of the display device ED-a may be improved, and the buckling phenomenon and crack that may be generated when the display device ED-a is folded may be reduced.

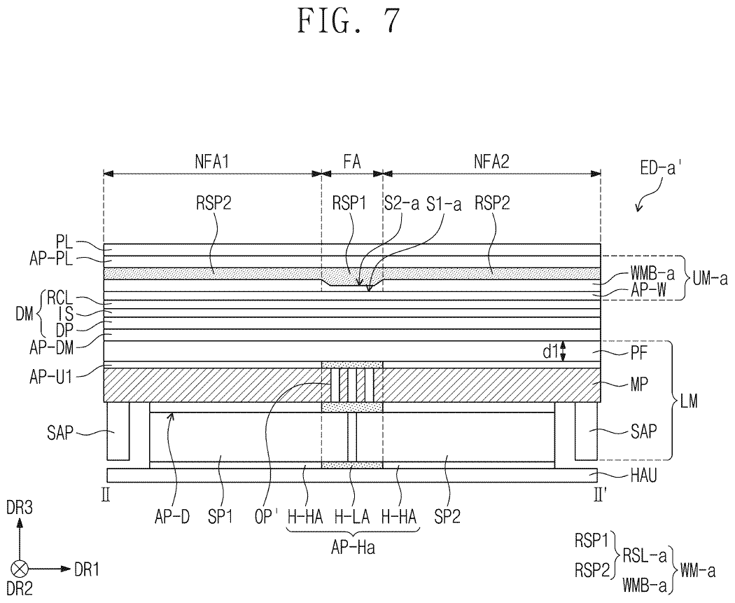

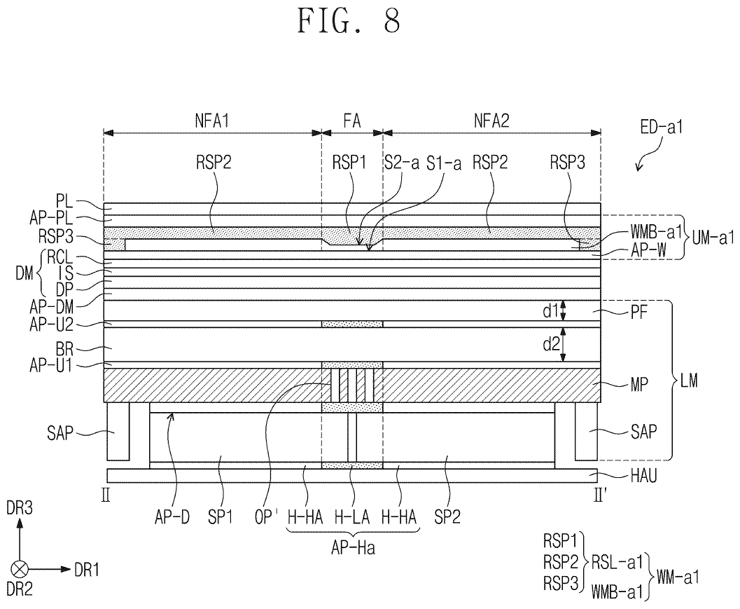

FIG. 7 is a cross-sectional view of a display device ED-a′ taken along the line II-II′ of FIG. 2 according to an embodiment of the present disclosure. FIG. 8 is a cross-sectional view of a display device ED-a1 taken along the line II-II′ of FIG. 2 according to an embodiment of the present disclosure. Unlike the display device ED-a of FIG. 5, the display device ED-a′ shown in FIG. 7 does not include some components. Unlike the resin layer RSL-a of FIG. 5, a resin layer of the display device ED-a1 of FIG. 8 further includes a third resin portion.

Referring to FIG. 7, unlike the display device ED-a shown in FIG. 5, the display device ED-a′ may not include the barrier layer BR. An upper adhesive layer AP-U1 of the display device ED-a′ may be attached to a lower protective film PF, and may fix the lower protective film PF to a support plate MP. Because the display device ED-a′ does not include the barrier layer BR when compared to a comparative display device, a thickness of the display device ED-a′ may be decreased. Accordingly, a repulsive force between the components of the display device ED-a′ may be reduced when the display device ED-a′ is folded, and as a result, the folding characteristics of the display device ED-a′ may be improved.

Referring to FIG. 8, an upper module (e.g., an upper layer or stack) UM-a1 of the display device ED-a1 may include a window base WMB-a1 and a resin layer RSL-a1. Unlike the window base WMB-a shown in FIG. 5, the window base WMB-a1 shown in FIG. 8 may overlap with a portion (e.g., with only a portion) of the display module DM. A size of a first surface S1-a1 and a size of a second surface S2-a1 when viewed in a plane (e.g., in a plan view) may be smaller than a size of the display module DM when viewed in the plane. In other words, the size of the window base WMB-a1 when viewed in the plane (e.g., in a plan view) may be smaller than the size of the display module DM when viewed in the plane.

The resin layer RSL-a1 may include a first resin portion RSP1, a second resin portion RSP2, and the third resin portion RSP3. The third resin portion RSP3 may be in contact with a side surface of the window base WMB-a1. The first resin portion RSP1, the second resin portion RSP2, and the third resin portion RSP3 may be provided integrally with each other. The resin layer RSL-a1 may have a larger contact area with the window base WMB-a1 compared to that of the resin layer RSL-a shown in FIG. 5. Thus, an adhesion between the resin layer RSL-a1 and the window base WMB-a1 may be increased, and the side surface of the window base WMB-a1 may be protected from external impacts.

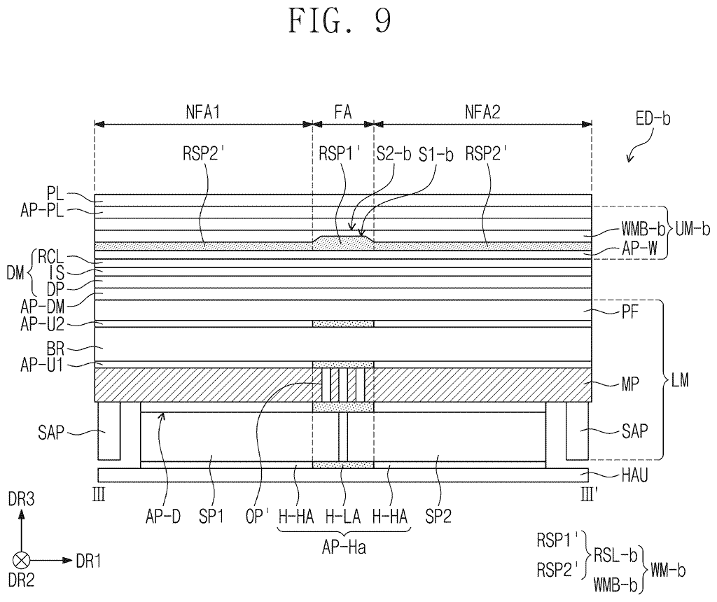

FIG. 9 is a cross-sectional view of the display device ED-b taken along the line III-III′ of FIG. 3 according to an embodiment of the present disclosure.

Referring to FIG. 9, an upper module (e.g., an upper layer or stack) UM-b of the display device ED-b may include a window base WMB-b and a resin layer RSL-b. Unlike the window base WMB-a shown in FIG. 5, the window base WMB-b shown in FIG. 9 may include a first surface S1-b adjacent to the display module DM and provided with a groove engraved therein. The groove may not be engraved in a second surface S2-b opposite to the first surface S1-b of the window base WMB-b. The resin layer RSL-b may have a Young's modulus equal to or greater than about 70 MPa and equal to or smaller than about 1000 MPa at a temperature of about-20 degrees Celsius, a Young's modulus equal to or greater than about 40 MPa and equal to or smaller than about 1000 MPa at a temperature of about 25 degrees Celsius, and a Young's modulus equal to or greater than about 20 MPa and equal to or smaller than about 1000 MPa at a temperature of about 60 degrees Celsius. As an example, in a case where the Young's modulus of the resin layer RSL-b is smaller than about 70 MPa at the temperature of about-20 degrees Celsius, a degree to which the resin layer RSL-b is folded may be greater than a degree to which the display module DM is folded when the display device ED-b is folded, and thus, the buckling phenomenon may occur. In a case where the Young's modulus of the resin layer RSL-b is greater than about 1000 MPa at the temperature of about-20 degrees Celsius, a crack may occur in a protective layer PL disposed on the resin layer RSL-b.

Hereinafter, the physical properties of the resin layer included in the display device according to some embodiments of the present disclosure will be described in more detail. In addition, the embodiments described below may be examples provided to help in the understanding of some aspects and features of the present disclosure, and thus, the present disclosure is not limited thereto or thereby.

Table 1 below shows, for the display device shown in FIG. 2, the strain (%) of each of the upper surface of the resin layer, the lower surface of the resin layer, and the window base, and the repulsive force (N) between the resin layer and the window base according to the Young's modulus of the resin layer when the display device is folded (e.g., the in-folding) about the folding axis with a radius of curvature of about 2.1 mm to allow the upper surface of the first non-folding portion and the upper surface of the second non-folding portion to be adjacent to each other in the same direction as that illustrated in FIG. 1B at the temperature of about 25 degrees Celsius. The lower surface of the resin layer indicates a surface that is in contact with the upper surface of the window base folding portion. In Table 1, BK denotes that the buckling phenomenon occurs, and CK denotes that the crack occurs in the protective layer disposed above the resin layer. In Table 1 and the below tables, as the absolute values of the strain of the upper surface of the resin layer, the strain of the lower surface of the resin layer, the strain of the window base, and the repulsive force increase, a likelihood of cracks occurring in the protective layer may increase, which may deteriorate the folding characteristics.

TABLE 1

| Young's | Strain (%) of | Strain (%) of | | |
|---|---|---|---|---|
| modulus | upper surface | lower surface | Strain | |
| (Mpa) of | of resin | of resin | (%) of | Repulsive |
| resin layer | layer | layer | window base | force (N) |
| 30 | BK | BK | BK | BK |
| 35 | −7.61 | −1.28 | 1.35 | 4.42 |
| 40 | −7.68 | −1.28 | 1.35 | 4.44 |
| 50 | −7.76 | −1.28 | 1.35 | 4.47 |
| 60 | −7.81 | −1.28 | 1.36 | 4.49 |
| 70 | −7.85 | −1.28 | 1.36 | 4.50 |
| 80 | −7.89 | −1.28 | 1.36 | 4.53 |
| 90 | −7.92 | −1.28 | 1.36 | 4.54 |
| 100 | −7.94 | −1.28 | 1.36 | 4.55 |
| 500 | −8.21 | −1.26 | 1.43 | 4.86 |
| 1000 | −8.37 | −1.25 | 1.49 | 5.10 |
| 1200 | CK | CK | CK | CK |
| 2000 | CK | CK | CK | CK |

Referring to Table 1, when the Young's modulus of the resin layer is smaller than about 35 MPa at the temperature of about 25 degrees Celsius, the buckling phenomenon occurs, and the resin layer may be detached from the window base due to the excessively low Young's modulus of the resin layer. When the Young's modulus of the resin layer is greater than about 1000 MPa, the crack may occur in the protective layer, and the force transmitted to the protective layer may induce the crack occurrence, because the force required to fold the resin layer may be excessively large. As the Young's modulus of the resin layer increases, the strain of the upper surface of the resin layer increases, the strain of the lower surface of the resin layer remains the same or decreases, and the strain of the window base increases. In addition, the repulsive force increases in proportion to the Young's modulus of the resin layer. When the Young's modulus of the resin layer is equal to or greater than about 35 MPa and equal to or smaller than about 1000 MPa at the temperature of about 25 degrees Celsius, the buckling phenomenon or the crack may not occur, and the folding characteristics of the display device may not be deteriorated.

Table 2 below shows, for the display device shown in FIG. 2, the strain (%) of each of the upper surface of the resin layer, the lower surface of the resin layer, and the window base, and the repulsive force (N) between the resin layer and the window base according to the Young's modulus of the resin layer when the display device is folded (e.g., the in-folding) about the folding axis with a radius of curvature of about 2.1 mm to allow the upper surface of the first non-folding portion and the upper surface of the second non-folding portion to be adjacent to each other in the same direction as that in FIG. 1B at the temperature of about 60 degrees Celsius.

TABLE 2

| Young's | Strain (%) of | Strain (%) of | | |
|---|---|---|---|---|
| modulus | upper surface | lower surface | | |
| (Mpa) of | of resin | of resin | Strain (%) of | Repulsive |
| resin layer | layer | layer | window base | force (N) |
| 5 | BK | BK | BK | BK |
| 30 | −7.64 | −1.28 | 1.33 | 3.48 |
| 35 | −7.70 | −1.28 | 1.33 | 3.49 |
| 40 | −7.74 | −1.28 | 1.33 | 3.51 |
| 50 | −7.80 | −1.28 | 1.33 | 3.53 |
| 60 | −7.84 | −1.28 | 1.34 | 3.54 |
| 70 | −7.88 | −1.28 | 1.34 | 3.55 |
| 80 | −7.91 | −1.28 | 1.34 | 3.57 |
| 90 | −7.93 | −1.28 | 1.34 | 3.58 |
| 100 | −7.94 | −1.27 | 1.34 | 3.59 |
| 500 | −8.19 | −1.26 | 1.41 | 3.88 |
| 1000 | −8.36 | −1.25 | 1.47 | 4.12 |
| 1200 | CK | CK | CK | CK |
| 2000 | CK | CK | CK | CK |

Referring to FIG. 2, when the Young's modulus of the resin layer is smaller than about 10 MPa at the temperature of about 60 degrees Celsius, the buckling phenomenon may occur, and the resin layer may be detached from the window base due to the excessively low Young's modulus of the resin layer. When the Young's modulus of the resin layer is greater than about 1000 MPa, the crack may occur in the protective layer, and the force transmitted to the protective layer may induce the crack occurrence, because the force required to fold the resin layer may be excessively large. As the Young's modulus of the resin layer increases, the strain of the upper surface of the resin layer increases, the strain of the lower surface of the resin layer remains the same or decreases, and the strain of the window base increases. In addition, the repulsive force increases in proportion to the Young's modulus of the resin layer. When the Young's modulus of the resin layer is equal to or greater than about 10 MPa and equal to or smaller than about 1000 MPa at the temperature of about 60 degrees Celsius, the buckling phenomenon or the crack may not occur, and the folding characteristics of the display device may not be deteriorated.

Table 3 below shows, for the display device shown in FIG. 2, the strain (%) of each of the upper surface of the resin layer, the lower surface of the resin layer, and the window base, and the repulsive force (N) between the resin layer and the window base according to the Young's modulus of the resin layer when the display device is folded (e.g., the in-folding) about the folding axis with a radius of curvature of about 2.1 mm to allow the upper surface of the first non-folding portion and the upper surface of the second non-folding portion to be adjacent to each other in the same direction as that in FIG. 1B at the temperature of about-20 degrees Celsius.

TABLE 3

| Young's | Strain (%) of | Strain (%) of | | |
|---|---|---|---|---|
| modulus | upper surface | lower surface | | |
| (Mpa) of | of resin | of resin | Strain (%) of | Repulsive |
| resin layer | layer | layer | window base | force (N) |
| 30 | BK | BK | BK | BK |
| 35 | BK | BK | BK | BK |
| 40 | BK | BK | BK | BK |
| 50 | BK | BK | BK | BK |
| 60 | −7.61 | −1.29 | 1.34 | 6.75 |
| 70 | −7.66 | −1.29 | 1.34 | 6.78 |
| 80 | −7.71 | −1.29 | 1.34 | 6.80 |
| 90 | −7.75 | −1.29 | 1.34 | 6.82 |
| 100 | −7.79 | −1.29 | 1.35 | 6.84 |
| 500 | −8.13 | −1.26 | 1.41 | 7.19 |
| 1000 | −8.28 | −1.25 | 1.46 | 7.45 |
| 1200 | CK | CK | CK | CK |
| 2000 | CK | CK | CK | CK |

Referring to Table 3, when the Young's modulus of the resin layer is smaller than about 60 MPa at the temperature of about-20 degrees Celsius, the buckling phenomenon may occur, and the resin layer may be detached from the window base due to the excessively low Young's modulus of the resin layer. When the Young's modulus of the resin layer is greater than about 1000 MPa, the crack may occur in the protective layer, and the force transmitted to the protective layer may induce the crack occurrence, because the force required to fold the resin layer may be excessively large. As the Young's modulus of the resin layer increases, the strain of the upper surface of the resin layer increases, the strain of the lower surface of the resin layer remains the same or decreases, and the strain of the window base increases. In addition, the repulsive force increases in proportion to the Young's modulus of the resin layer. When the Young's modulus of the resin layer is equal to or greater than about 60 MPa and equal to or smaller than about 1000 MPa at the temperature of about-20 degrees Celsius, the buckling phenomenon or the crack may not occur, and the folding characteristics of the display device may not be deteriorated.

Table 4 below shows, for the display device shown in FIG. 3, the strain (%) of each of the resin layer and the window base, and the repulsive force (N) between the resin layer and the window base according to the Young's modulus of the resin layer when the display device is folded (e.g., the out-folding) about the folding axis with a radius of curvature of about 2.1 mm to allow the lower surface of the first non-folding portion and the lower surface of the second non-folding portion to be adjacent to each other in the same direction as that in FIG. 1C at the temperature of about 25 degrees Celsius.

TABLE 4

| Young's | | | |
|---|---|---|---|
| modulus (Mpa) | Strain (%) of resin | Strain (%) of window | Repulsive |
| of resin layer | layer | base | force (N) |
| 30 | BK | BK | BK |
| 35 | BK | BK | BK |
| 40 | 6.80 | 1.23 | 4.70 |
| 50 | 6.89 | 1.24 | 4.73 |
| 60 | 6.95 | 1.24 | 4.75 |
| 70 | 6.97 | 1.24 | 4.75 |
| 80 | 7.00 | 1.24 | 4.77 |
| 90 | 7.03 | 1.24 | 4.78 |
| 100 | 7.08 | 1.24 | 4.80 |
| 500 | 7.45 | 1.26 | 5.07 |
| 1000 | 7.69 | 1.28 | 5.29 |
| 1200 | CK | CK | CK |
| 2000 | CK | CK | CK |

Referring to Table 4, when the Young's modulus of the resin layer is smaller than about 40 MPa at the temperature of about 25 degrees Celsius, the buckling phenomenon may occur, and the resin layer may be detached from the window base due to the excessively low Young's modulus of the resin layer. When the Young's modulus of the resin layer is greater than about 1000 MPa, the crack may occur in the protective layer, and the force transmitted to the protective layer may induce the crack occurrence, because the force required to fold the resin layer may be excessively large. As the Young's modulus of the resin layer increases, the strain of the resin layer, the strain of the window base, and the repulsive force increase. When the Young's modulus of the resin layer is equal to or greater than about 40 MPa and equal to or smaller than about 1000 MPa at the temperature of about 25 degrees Celsius, the buckling phenomenon or the crack may not occur, and the folding characteristics of the display device may not be deteriorated.

Table 5 below shows, for the display device shown in FIG. 3, the strain (%) of each of the resin layer and the window base, and the repulsive force (N) between the resin layer and the window base according to the Young's modulus of the resin layer when the display device is folded (e.g., the out-folding) about the folding axis with a radius of curvature of about 2.1 mm to allow the lower surface of the first non-folding portion and the lower surface of the second non-folding portion to be adjacent to each other in the same direction as that in FIG. 1C at the temperature of about 60 degrees Celsius.

TABLE 5

| Young's | | | |
|---|---|---|---|
| modulus (Mpa) | Strain (%) of resin | Strain (%) of window | Repulsive |
| of resin layer | layer | base | force (N) |
| 10 | BK | BK | BK |
| 30 | 6.83 | 1.26 | 3.63 |
| 35 | 6.86 | 1.25 | 3.64 |
| 40 | 6.93 | 1.26 | 3.66 |
| 50 | 6.99 | 1.26 | 3.67 |
| 60 | 7.03 | 1.26 | 3.69 |
| 70 | 7.03 | 1.26 | 3.69 |
| 80 | 7.06 | 1.26 | 3.70 |
| 90 | 7.08 | 1.26 | 3.71 |
| 100 | 7.12 | 1.26 | 3.73 |
| 500 | 7.44 | 1.28 | 3.99 |
| 1000 | 7.66 | 1.30 | 4.21 |
| 1200 | CK | CK | CK |
| 2000 | CK | CK | CK |

Referring to Table 5, when the Young's modulus of the resin layer is smaller than about 20 MPa at the temperature of about 60 degrees Celsius, the buckling phenomenon may occur, and the resin layer may be detached from the window base due to the excessively low Young's modulus of the resin layer. When the Young's modulus of the resin layer is greater than about 1000 MPa, the crack may occur in the protective layer, and the force transmitted to the protective layer may induce the crack occurrence, because the force required to fold the resin layer may be excessively large. As the Young's modulus of the resin layer increases, the strain of the resin layer, the strain of the window base, and the repulsive force increase. When the Young's modulus of the resin layer is equal to or greater than about 20 MPa and equal to or smaller than about 1000 MPa at the temperature of about 60 degrees Celsius, the buckling phenomenon or the crack may not occur, and the folding characteristics of the display device may not be deteriorated.

Table 6 below shows, for the display device shown in FIG. 3, the strain (%) of each of the resin layer and the window base, and the repulsive force (N) between the resin layer and the window base according to the Young's modulus of the resin layer when the display device is folded (e.g., the out-folding) about the folding axis with a radius of curvature of about 2.1 mm to allow the lower surface of the first non-folding portion and the lower surface of the second non-folding portion to be adjacent to each other in the same direction as that in FIG. 1C at the temperature of about-20 degrees Celsius.

TABLE 6

| Young's | | | |
|---|---|---|---|
| modulus (Mpa) | Strain (%) of resin | Strain (%) of window | Repulsive |
| of resin layer | layer | base | force (N) |
| 30 | BK | BK | BK |
| 35 | BK | BK | BK |
| 40 | BK | BK | BK |
| 50 | BK | BK | BK |
| 60 | BK | BK | BK |
| 70 | 6.85 | 1.19 | 7.99 |
| 80 | 6.93 | 1.19 | 8.02 |
| 90 | 6.98 | 1.19 | 8.05 |
| 100 | 7.09 | 1.20 | 8.09 |
| 500 | 7.63 | 1.23 | 8.47 |
| 1000 | 7.94 | 1.26 | 8.66 |
| 1200 | CK | CK | CK |
| 2000 | CK | CK | CK |

Referring to Table 6, when the Young's modulus of the resin layer is smaller than about 70 MPa at the temperature of about-20 degrees Celsius, the buckling phenomenon may occur, and the resin layer may be detached from the window base due to the excessively low Young's modulus of the resin layer. When the Young's modulus of the resin layer is greater than about 1000 MPa, the crack may occur in the protective layer, and the force transmitted to the protective layer may induce the crack occurrence, because the force required to fold the resin layer may be excessively large. As the Young's modulus of the resin layer increases, the strain of the resin layer, the strain of the window base, and the repulsive force increase. When the Young's modulus of the resin layer is equal to or greater than about 70 MPa and equal to or smaller than about 1000 MPa at the temperature of about-20 degrees Celsius, the buckling phenomenon or the crack may not occur, and the folding characteristics of the display device may not be deteriorated.

According to Tables 1 to 6, when the display device shown in FIG. 2 is inwardly folded, and the Young's modulus of the resin layer is equal to or greater than about 60 MPa and equal to or smaller than about 1000 MPa at the temperature of about-20 degrees Celsius, equal to or greater than about 35 MPa and equal to or smaller than about 1000 MPa at the temperature of about 25 degrees Celsius, and equal to or greater than about 10 MPa and equal to or smaller than about 1000 MPa at the temperature of about 60 degrees Celsius, the buckling phenomenon or the crack occurrence may be improved. In addition, when the display device shown in FIG. 3 is outwardly folded, and the Young's modulus of the resin layer is equal to or greater than about 70 MPa and equal to or smaller than about 1000 MPa at the temperature of about-20 degrees Celsius, equal to or greater than about 40 MPa and equal to or smaller than about 1000 MPa at the temperature of about 25 degrees Celsius, and equal to or greater than about 20 MPa and equal to or smaller than about 1000 MPa at the temperature of about 60 degrees Celsius, the buckling phenomenon or the crack occurrence may be improved.

Table 7 below shows the force (hereinafter referred to as a breaking force) applied to a pen to the display device when the window is broken by the pen during a pen drop test conducted on the display device including the display module and the window after the display device is placed on a surface plate with a thickness of about 10 cm. The breaking force is presented according to the thickness (μm) of the window.

TABLE 7

| | Window thickness (μm) | | | | | | |
|---|---|---|---|---|---|---|---|
| | 30 | 50 | 70 | 80 | 90 | 100 | 150 |
| Breaking | 1.00 | 1.53 | 2.50 | 2.97 | 3.40 | 3.62 | 6.20 |
| force (kgf) | | | | | | | |

Referring to FIG. 7, the thickness of the window is proportional to the breaking force, and the breaking force when the thickness of the window is about 50 micrometers is about 53% higher than the breaking force when the thickness of the window is about 30 micrometers. In addition, the breaking force when the thickness of the window is about 150 micrometers is about 248% higher than the breaking force when the thickness of the window is about 70 micrometers. Because the window base of the display device according to some embodiments of the present disclosure has the thickness greater than that of the comparative window base, the durability of the display device according to some embodiments of the present disclosure may be improved. As an example, according to the window base of the display device of some embodiments of the present disclosure, the thickness of the folding portion may be about 50 micrometers, and the thickness of the non-folding portion may be about 150 micrometers. According to the window base of the comparative display device, the thickness of the folding portion is about 30 micrometers, and the thickness of the non-folding portion is about 70 micrometers. When compared to the comparative display device, the durability of the display device according to some embodiments of the present disclosure may be significantly improved.

Table 8 below shows a total thickness (μm), a strain (%) of the resin layer, a strain (%) of the window base, and a repulsive force (N) between the resin layer and the window base according to the stacked structure of the display device. In each of the display devices according to comparative examples and the embodiment examples, the stacking order from the bottom is as follows: the barrier layer BR, upper adhesive layers AP-U2, a lower protective film PF, a module adhesive layer AP-DM, the display panel DP, the window adhesive layer AP-W, the window base WMB, the resin layer RSL, the protective layer adhesive layer AP-PL, the protective layer PL, and the coating layer HC. Table 8 shows a thickness (μm) of each of the above-described layers, and X indicates that the corresponding component is not included.

In the display device of comparative example 1, a groove is not formed in a window base, and the window base has a flat shape. In the display device of comparative example 2 and the display devices of embodiment examples 1 to 7, the groove is formed in the folding portion of the window base. The thickness (μm) of the window base is given for the folding portion and the non-folding portion in that order. In the display device of comparative example 2 and the display devices of embodiment examples 1 to 7, the resin layer is disposed in the groove and is also disposed on the non-folding portion. The thickness (mm) of the resin layer refers to the thickness of a portion of the resin layer that is disposed on the non-folding portion. The total thickness (μm) is the sum of the thicknesses of all layers, and the strain (%) of the resin layer, the strain (%) of the window base, and the repulsive force (N) are identical in concept to the strain (%) of the upper surface of the resin layer, the strain (%) of the window base, and the repulsive force (N) between the resin layer and the window base defined in Table 1.

TABLE 8

| | | Comparative | Comparative | Embodiment | Embodiment | Embodiment | Embodiment | Embodiment | Embodiment | Embodiment |
|---|---|---|---|---|---|---|---|---|---|---|
| | | example | example | example | example | example | example | example | example | example |
| | | 1 | 2 | 1 | 2 | 3 | 4 | 5 | 6 | 7 |
| Structure | HC | 5 | 5 | 5 | 5 | 5 | 5 | 5 | 5 | 5 |
| | PL | 50 | 50 | 50 | 50 | 50 | 50 | 50 | 30 | 35 |
| | AP-PL | 25 | 25 | 25 | 25 | 25 | 25 | 25 | 25 | 25 |
| | RSL | X | 20 | 20 | 20 | 20 | 20 | 10 | 10 | 10 |
| | WMB | 50 | 50/90 | 50/150 | 50/150 | 50/150 | 50/150 | 50/150 | 50/150 | 50/150 |
| | AP-W | 75 | 75 | 75 | 50 | 50 | 50 | 50 | 50 | 50 |
| | DP | 30 | 30 | 30 | 30 | 30 | 30 | 30 | 30 | 30 |
| | AP-DM | 18 | 18 | 18 | 18 | 18 | 18 | 18 | 18 | 18 |
| | PF | 50 | 50 | 50 | 50 | 50 | 50 | 50 | 50 | 40 |
| | AP-U2 | 25 | 25 | 25 | 25 | 25 | X | X | X | X |
| | BR | 35 | 35 | 35 | 35 | 25 | X | X | X | X |

| | | | | | | | | | |
|---|---|---|---|---|---|---|---|---|---|
| Total | 3z3 | 423 | 483 | 458 | 448 | 398 | 388 | 368 | 363 |
| thickness (μm) | | | | | | | | | |
| Strain (%) of | — | −4.53 | −7.85 | −7.85 | −7.83 | −7.81 | −7.22 | −7.28 | 7.26− |
| resin layer | | | | | | | | | |
| Strain (%) of | 1.29 | 1.29 | 1.36 | 1.35 | 1.35 | 1.36 | 1.34 | 1.30 | 1.31 |
| window base | | | | | | | | | |
| repulsive | 2.74 | 3.34 | 4.50 | 4.38 | 4.22 | 3.80 | 3.56 | 2.93 | 3.01 |
| force (N) | | | | | | | | | |

Referring to FIG. 8, as the total thickness decreases, the strain of the resin layer, the strain of the window base, and the repulsive force tend to decrease. The display devices of embodiment examples 1 to 7 have high repulsive force compared to that of the display device of comparative example 1, but have superior folding characteristics because the groove is formed in the folding portion of the window base. The thickness of the window base of the display devices of embodiment examples 1 to 7 may be greater than the thickness of the window base of the display devices of comparative examples 1 and 2, and thus, the durability of the display devices of embodiment examples 1 to 7 may be improved.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated.

Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. An electronic device comprising:
a display module; and
a window on the display module, the window comprising:
a window base on the display module, and comprising:
a folding portion having one surface of the window base partially engraved by a groove; and
a first non-folding portion and a second non-folding portion spaced from each other with the folding portion between the first and second non-folding portions; and
a resin layer on the one surface of the window base, and comprising:
a first resin portion on the folding portion to fill the groove; and
a second resin portion on the first non-folding portion and the second non-folding portion,
wherein the resin layer has a Young's modulus equal to or greater than about 60 MPa and equal to or smaller than about 1000 MPa at a temperature of about-20 degrees Celsius, equal to or greater than about 35 MPa equal to or smaller than about 1000 MPa at a temperature of about 25 degrees Celsius, and equal to or greater than about 10 MPa equal to or smaller than about 1000 MPa at a temperature of about 60 degrees Celsius.

2. The electronic device of claim 1, wherein the folding portion comprises a first surface adjacent to the display module, and a second surface opposite to the first surface, and
wherein the groove is engraved in the first surface.

3. The electronic device of claim 2, wherein the Young's modulus of the resin layer is equal to or greater than about 70 MPa and equal to or smaller than about 1000 MPa at a temperature of about-20 degrees Celsius, equal to or greater than about 40 MPa equal to or smaller than about 1000 MPa at a temperature of about 25 degrees Celsius, and equal to or greater than about 20 MPa equal to or smaller than about 1000 MPa at a temperature of about 60 degrees Celsius.

4. The electronic device of claim 1, wherein the folding portion comprises a first surface adjacent to the display module, and a second surface opposite to the first surface, and
wherein the groove is engraved in the second surface.

5. The electronic device of claim 1, wherein:
the first non-folding portion comprises a first non-folding surface;
the second non-folding portion comprises a second non-folding surface; and
the folding portion comprises a flat surface, a first slant surface connecting the flat surface and the first non-folding surface to each other, and a second slant surface connecting the flat surface and the second non-folding surface to each other.

6. The electronic device of claim 5, wherein the first resin portion is in contact with each of the flat surface, the first slant surface, and the second slant surface.

7. The electronic device of claim 5, wherein the groove comprises the flat surface, the first slant surface, and the second slant surface.

8. The electronic device of claim 1, wherein the resin layer has a refractive index equal to or greater than about 1.45 and equal to or smaller than about 1.54 with respect to visible light.

9. The electronic device of claim 1, wherein an absolute value of a crack strain of the resin layer is equal to or smaller than about 10%.

10. The electronic device of claim 1, wherein:
the folding portion has a thickness equal to or greater than about 30 micrometers and equal to or smaller than about 70 micrometers;
the first non-folding portion has a thickness equal to or greater than about 120 micrometers and equal to or smaller than about 180 micrometers; and
the second non-folding portion has a thickness equal to or greater than about 120 micrometers and equal to or smaller than about 180 micrometers.

11. The electronic device of claim 1, wherein the resin layer further comprises a third resin portion in contact with a side surface of the window base.

12. The electronic device of claim 11, wherein the first resin portion, the second resin portion, and the third resin portion are integral with each other.

13. The electronic device of claim 1, wherein the first resin portion has a thickness equal to or greater than about 50 micrometers and equal to or smaller than about 150 micrometers, and the second resin portion has a thickness equal to or greater than about 5 micrometers and equal to or smaller than about 30 micrometers.

14. A display device comprising:
a lower protective film;
a base layer on the lower protective film;
a display element layer on the base layer; and
a window comprising:
a window base on the display element layer, and comprising:
a folding portion having one surface of the window base engraved by a groove; and
a first non-folding portion and a second non-folding portion spaced from each other with the folding portion between the first and second non-folding portions; and
a resin layer on the one surface of the window base,
wherein the resin layer has a Young's modulus equal to or greater than about 60 MPa and equal to or smaller than about 1000 MPa at a temperature of about-20 degrees Celsius, equal to or greater than about 35 MPa equal to or smaller than about 1000 MPa at a temperature of about 25 degrees Celsius, and equal to or greater than about 10 MPa and equal to or smaller than about 1000 MPa at a temperature of about 60 degrees Celsius.

15. The display device of claim 14, wherein the resin layer comprises:
a first resin portion directly in the groove; and
a second resin portion directly on the first non-folding portion and the second non-folding portion.

16. The display device of claim 14, further comprising a barrier layer on a lower surface of the lower protective film.

17. The display device of claim 16, wherein the barrier layer has a thickness equal to or greater than about 20 micrometers and equal to or smaller than about 40 micrometers.

18. The display device of claim 14, further comprising a protective layer on the resin layer.

19. The display device of claim 18, wherein the protective layer has a thickness equal to or greater than about 30 micrometers and equal to or smaller than about 60 micrometers.

20. The display device of claim 14, wherein:
the folding portion comprises a first surface adjacent to the display element layer, and a second surface opposite to the first surface;
the groove is engraved in the first surface; and
the Young's modulus of the resin layer is equal to or greater than about 70 MPa and equal to or smaller than about 1000 MPa at a temperature of about-20 degrees Celsius, equal to or greater than about 40 MPa equal to or smaller than about 1000 MPa at a temperature of about 25 degrees Celsius, and equal to or greater than about 20 MPa equal to or smaller than about 1000 MPa at a temperature of about 60 degrees Celsius.
